(19) United States
(12) Patent Application Publication
(10) Pub. No.: US 2008/0217755 A1
(43) Pub. Date: Sep. 11, 2008

(54) Systems and Methods for Providing Voltage Compensation in an Integrated Circuit Chip Using a Divided Power Plane

(76) Inventor: Satoru Takase, Kanagawa (JP)

Correspondence Address: LAW OFFICES OF MARK L. BERRIER, 3811 BEE CAVES ROAD, SUITE 204, AUSTIN, TX, 78746, US

(21) Appl. No.: 11/684,181

(22) Filed: Mar. 9, 2007

(51) Int. Cl. H01L 23/50; H01L 21/60; H01L 21/66

(52) U.S. Cl. 257/691; 438/6; 257/E23.079; 257/E21.526; 257/E21.531

(57) ABSTRACT

Systems and methods for providing power to on-chip components of an integrated circuit with improved uniformity through the use of a split power plane. One embodiment comprises a system having an integrated circuit chip, a power distribution network coupled to the integrated circuit chip, and a power plane coupled to the power distribution network. The power plane is divided into two or more separate sections, each of which is separately connected to the power distribution network. One or more power sources can be connected to the different power plane sections to apply different voltages to the different sections, thereby compensating for different resistances in the different portions of the power distribution network

### BACKGROUND

1. Field of the Invention

The invention relates generally to the design of integrated circuits, and more particularly to systems and methods for providing power to on-chip components of an integrated circuit with improved uniformity through the use of a split power plane.

2. Related Art

Integrated circuits contain many individual electronic components, such as transistors, resistors, capacitors, diodes, and the like, which are arranged and interconnected to form larger components, such as logic gates, memory cells, sense amplifiers, etc. These components form even larger components, such as processor cores, bus controllers, and so on, which are used to build devices such as computers, cell phones, PDAs, etc. These electrical components and devices, however, cannot operate without power. It is therefore necessary, when constructing these components and devices, to provide a power distribution network that can supply power from a source which is an external to the integrated circuit to each of the on-chip components of the integrated circuit.

Typically, a power distribution network in an integrated circuit includes multiple metal layers and multiple layers of vias that interconnect the metal layers. The power distribution network also includes contacts for connection to the external power source, as well as contacts to the components of the integrated circuit. Conventionally, each metal layer includes traces that are oriented in a single direction, and the traces of successive metal layers are oriented in different (perpendicular) directions. Power supplied to the power distribution network at a given contact can therefore be transmitted to a wider area on the chip by connecting the contact to a first trace which extends in one direction, and then connecting the first trace to further traces which extend in the other direction, and so on through the different layers of the power distribution network.

Since the power distribution network of the integrated circuit has its own inherent electrical characteristics, it will affect the power provided to the components of the integrated circuit. For example, because the power distribution network has resistance, it will dissipate some amount of power, and the voltage provided to the integrated circuit components will be somewhat less than the voltage at the contacts to the external power source. It is also important to note that the power distribution network consists of many components, and that variations in the resistance of each component may affect the resistance between the external contacts and the on-chip components of the integrated circuit. This effect is greatest in the area of the chip nearest the component, but extends outward from this point to some degree. As a result, manufacturing variations that affect the resistance of the power distribution network components may affect the uniformity of the network's resistance across the integrated circuit.

Because the resistance of the power distribution network may vary across the integrated circuit chip, the voltage supplied through the power distribution network may also vary. The voltage supplied at one point on the integrated circuit chip may therefore be lower than the voltage supplied at another point on the chip. If the reduced voltage at the first point is less than a voltage at which the integrated circuit is designed to operate, the integrated circuit may malfunction. Conventionally, this problem is addressed by increasing the voltage applied to the external contacts of the power distribution network, so that the voltage supplied at each point on the integrated circuit chip is no less than the design voltage. While this reduces the probability of a malfunction resulting from a below-minimum voltage at the first point, it is expensive in terms of the overall power budget, since other points will operate at voltages which are higher than necessary.

It would therefore be desirable to provide systems and methods for increasing the voltages that are supplied to selected areas of the integrated circuit without increasing the voltages in areas where it is not necessary to do so.

### SUMMARY OF THE INVENTION

One or more of the problems outlined above may be solved by the various embodiments of the invention. Broadly speaking, the invention includes systems and methods for providing power to on-chip components of an integrated circuit with improved uniformity through the use of a split power plane.

One embodiment comprises a system having an integrated circuit chip, a power distribution network coupled to the integrated circuit chip, and a power plane coupled to the power distribution network. The power plane is divided into two or more separate sections, each of which is separately connected to the power distribution network. The separate power plane sections enable different voltages to be applied to different portions of the power distribution network to compensate for different resistances in the respective portions, thereby providing a substantially uniform voltage across the integrated circuit chip.

In one embodiment, the power distribution network includes alternating layers of metal traces and vias, as well as a layer of contacts which connect an uppermost one of the metal layers to the power plane. The power plane is split in same direction as the uppermost metal layer to form the separate sections, so that each trace in a top metal layer is connected by contacts to no more than one of the sections of the power plane. The resistance between each of the power plane sections and the integrated circuit chip may be different, so the system may also include one or more power sources coupled to the different sections of the power plane. The power sources can supply different voltages to the different power plane sections (higher voltages to higher-resistance portions of the power distribution network) to produce a more uniform voltage across the integrated circuit chip.

Another embodiment comprises a method including the steps of providing an integrated circuit having a power plane which is divided into two or more separate power plane sections connected to a power distribution network, applying a first voltage to one of the power plane sections, and applying a different voltage to another one of the power plane sections. In one embodiment, a portion of the power distribution network having a resistance which is too high (resulting in a chip voltage which is too low) is identified, and the power plane is divided so that there is a separate section corresponding to this portion of the power distribution network. The power plane may, for example, be manufactured as a single piece which is cut after the high-resistance portion of the power distribution network is identified. Alternatively, the power plane may be tested as a single piece and then replaced by a plane with multiple sections after the high-resistance portion of the power distribution network is identified. Since this portion of the power distribution network has a higher resistance than other portions of the network, a higher voltage is applied to the corresponding power plane section in order to compensate for the higher voltage drop in the power distribution network.

Numerous additional embodiments are also possible.

The various embodiments of the present invention may provide a number of advantages over the prior art. One of the greatest advantages is that the voltage provided to the integrated circuit chip can be selectively increased in areas where the voltage is too low, without increasing the voltage across the entire chip. The selective increase of the voltage in the desired area(s) reduces the overall power consumption of the integrated circuit because the voltage is not increased in areas where the voltage is already high enough.

### BRIEF DESCRIPTION OF THE DRAWINGS

Other objects and advantages of the invention may become apparent upon reading the following detailed description and upon reference to the accompanying drawings.

FIG. 1 is a diagram illustrating a perspective view of several of the metal layers of a typical power distribution network.

FIG. 2 is a diagram illustrating a cross-sectional view of the structure of a typical power distribution network.

FIG. 3 is a diagram illustrating the relative contributions of the different layers in an exemplary power distribution network to the overall resistance of the network.

FIG. 4 is a diagram illustrating the nominal values of the resistance contributions of each layer in the exemplary power distribution network, as well as the ranges over which these values may vary from device to device.

FIG. 5 is a diagram illustrating the effect of locally varying component resistances in a power distribution network.

FIG. 6 is a diagram illustrating the configuration of the traces and C4 contacts in the top metal layer of a power distribution network.

FIG. 7 is a diagram illustrating the use of a divided power plane to achieve localized increases in voltage at the silicon level of an integrated circuit.

FIG. 8 is a top view of the power distribution network of FIG. 7.

FIG. 9 is a flow diagram illustrating a method for correcting silicon-level voltage variations arising from corresponding manufacturing variations in a power distribution network.

While the invention is subject to various modifications and alternative forms, specific embodiments thereof are shown by way of example in the drawings and the accompanying detailed description. It should be understood that the drawings and detailed description are not intended to limit the invention to the particular embodiments which are described. This disclosure is instead intended to cover all modifications, equivalents and alternatives falling within the scope of the present invention as defined by the appended claims.

### DETAILED DESCRIPTION OF EXEMPLARY EMBODIMENTS

One or more embodiments of the invention are described below. It should be noted that these and any other embodiments described below are exemplary and are intended to be illustrative of the invention rather than limiting.

Broadly speaking, the invention includes systems and methods for providing power to on-chip components of an integrated circuit with improved uniformity through the use of a divided power plane that allows different voltages to be applied to different parts of a power distribution network.

One embodiment of the invention is implemented in an integrated circuit. A power distribution network is connected to the semiconductor material (the chip) of the integrated circuit. A power plane is connected to the power distribution network, and a power source is connected to the power plane. Thus, the power source applies a voltage to the power plane, current flows through the power plane and the power distribution network, and a voltage is applied to the integrated circuit chip.

Because of manufacturing variations in the components of the power distribution network, the resistance of the network between the power plane and the chip may vary from one portion to another. In this embodiment, a portion which has a higher resistance (and consequently supplies a reduced voltage to the chip) is identified, and a corresponding section of the power plane is split apart from the other section(s). A higher voltage is applied to the section corresponding to the higher resistance than to the other section(s). The higher voltage compensates for the higher resistance, resulting in a more uniform voltage across the integrated circuit chip.

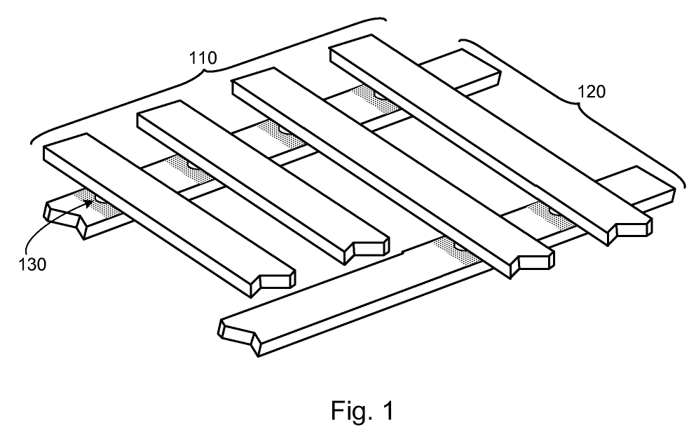

Before describing the exemplary embodiments of the invention in detail, it will be helpful to examine the structure of the power distribution network which is to be modeled. As noted above, the power distribution network consists of various layers that form and interconnecting network extending from an external power source to the various on-chip components of the integrated circuit. Referring to FIG. 1, a diagram providing a perspective view of several of these layers is shown. More specifically, FIG. 1 shows two of the metal layers in the network. It can be seen that the upper metal layer 110 consists of a series of traces that are oriented in a first direction. A lower metal layer 120 has a similar series of traces, but the traces are oriented in a second direction which is perpendicular to the first direction. Between layers 110 and 120 is a layer of vias 130 that connect traces in layer 110 to traces in layer 120. By in the traces of the different metal layers, power can be distributed to many different points across the area of the integrated circuit.

It should be noted that, for the purposes of this disclosure, references to the “top” or “upper” part of the power distribution network mean the part nearest the external power source. References to the “bottom” or “lower” part of the power distribution network mean the part nearest the silicon of the integrated circuit chip. It should also be noted that while the exemplary embodiments described herein concern a silicon-based integrated circuit, alternative embodiments may be implemented in integrated circuits that are constructed using other semiconductor materials. References herein to silicon should therefore be construed to include other types of semiconductor materials as well.

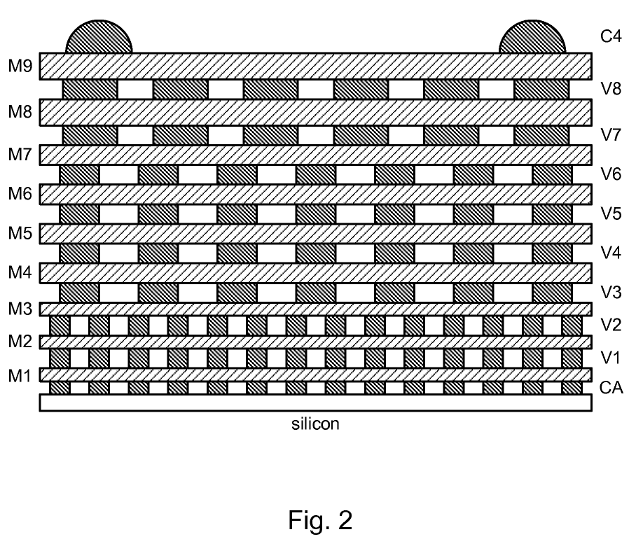

Referring to FIG. 2, a diagram illustrating a cross-sectional view of the structure of the power distribution network is shown. The power distribution network depicted in this figure includes nine different metal layers, indicated as M1-M9. (While the traces of successive metal layers are oriented in different directions, these layers are depicted as solid, unbroken layers for purposes of clarity.) Between the metal layers are eight layers of vias, indicated as V1-V8. The traces of layer M1 are connected to the traces of layer M2 by vias in layer V1, traces of layer M2 are connected to traces of layer M3 by vias in layer V2, and so on. There are also two layers (CA and C4) which consist of contacts. Contact layer CA connects traces of metal layer M1 to components on the surface of the integrated circuit chip, while contact layer C4 connects traces of metal layer M9 to the external power source. It should be noted that the figure depicts only a small portion of the power distribution network, and that the network may include many more contacts, traces and vias.

It can be seen that there are some differences between the various layers shown in FIG. 2. For example, the metal layers have several different thicknesses. Likewise, the vias in the different layers have varying sizes and spacings. The contacts in layer CA also have different sizes and spacings than the contacts in layer C4. These differences may result from a variety of design considerations. For example, the traces in metal layer M9 may have to carry larger currents than the traces of lower metal layers, so it may be necessary to make these traces wider and more thick than the traces in the lower layers. The same may be true of the contacts and vias in the other layers. As a result of these differences, each layer may have different electrical characteristics. For instance, because the contacts in layer C4 may be fewer in number and larger than the contacts in layer CA, the contacts in layer C4 may have a greater resistance per unit area than the contacts in layer CA.

As pointed out above, the characteristics of the power actually provided to components of the integrated circuit are not identical to the characteristics of the power applied by the power source at the external (C4) contacts of the power distribution network because of the electrical characteristics of the power distribution network itself. For instance, there may be defects in the traces or vias that cause them to have resistance values which are higher or lower than nominal design values. These variations in the resistances of the traces and/or vias result then cause variations in the resistance of the power distribution network. Moreover, because the defects (or manufacturing variations) in the components may not be homogeneous throughout the layers of the power distribution network, there may be local variations in the resistance of the network.

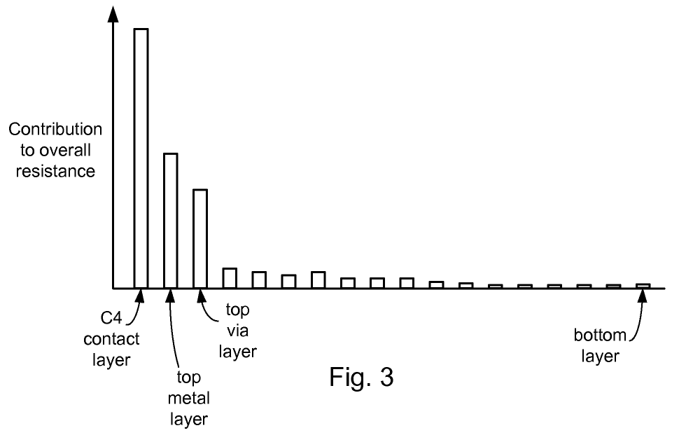

Referring to FIG. 3, a diagram illustrating the relative contributions of the different layers in an exemplary power distribution network to the overall resistance of the network is shown. Each vertical bar in this figure corresponds to one of the layers in the power distribution network. The bars toward the left side of the figure represent the upper layers of the network, while the bars on the right side of the figure represent the lower layers of the network. FIG. 3 depicts the resistance contributions of the contact layers, metal layers and via layers, but not the power plane.

It can be seen that the left-most bar in the figure, representing the layer of C4 contacts, makes the greatest contribution to the overall resistance of the exemplary power distribution network. The next bar, representing the uppermost metal layer in the power distribution network, makes the second greatest contribution to the resistance of the network, while the third bar, representing the uppermost via layer, makes the third greatest contribution to the overall resistance. The remainder of the layers in the power distribution network make relatively small contributions to the overall network resistance. In fact, the C4 contacts, top metal and top via layers account for about 75% of the overall resistance of the power distribution network in this example.

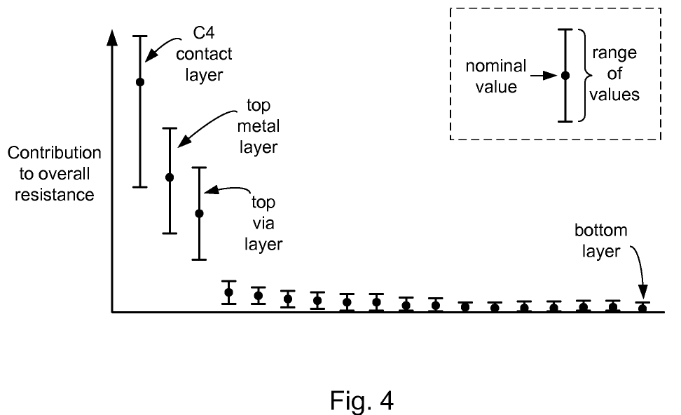

As noted above, the components of the power distribution network are subject to manufacturing variations, just as the components of other types of circuitry are subject to these variations. As a result, the resistance contributions illustrated in FIG. 3 may vary from one device to another. These variations are illustrated in FIG. 4. FIG. 4 is a diagram illustrating the nominal values of the resistance contributions of each layer in the exemplary power distribution network (represented by the dots,) as well as the ranges over which these values may vary from device to device (represented by the vertical bars.)

Referring to FIG. 4, the diagram is again arranged with the upper layers of the power distribution network represented toward the left side of the figure and the lower layers of the network represented toward the right side of the figure. It can be seen that the range of values which are typically experienced for each layer corresponds generally to the magnitude of that layer's contribution to the overall resistance. In other words, the layer of C4 contacts has the greatest nominal contribution to the network resistance, and also has the widest range of values. The uppermost metal layer has the second greatest contribution to the resistance and the second widest range of values, while the uppermost via layer has the third greatest contribution to the resistance and the third widest range of values. The remaining layers have relatively low contributions to the power distribution network resistance, and relatively narrow ranges of values.

The significance of the variation in the resistance contributions of the different layers of the power distribution network is that manufacturing variations which cause changes in the resistance of components in the top three layers (C4 contacts, top metal and top via) can have significant impact on the overall resistance of the network. Further, because the individual components (i.e., contacts, traces, vias) within the layers can have widely varying resistances, the variations may have localized effects on the resistance of the power distribution network. In other words, the resistance of the power distribution network between the external power source and different portions of the integrated circuit chip may vary. If the same voltage is applied to all of the external (C4) contacts of the power distribution network, the differences in resistance will result in different voltages being applied to different parts of the integrated circuit chip.

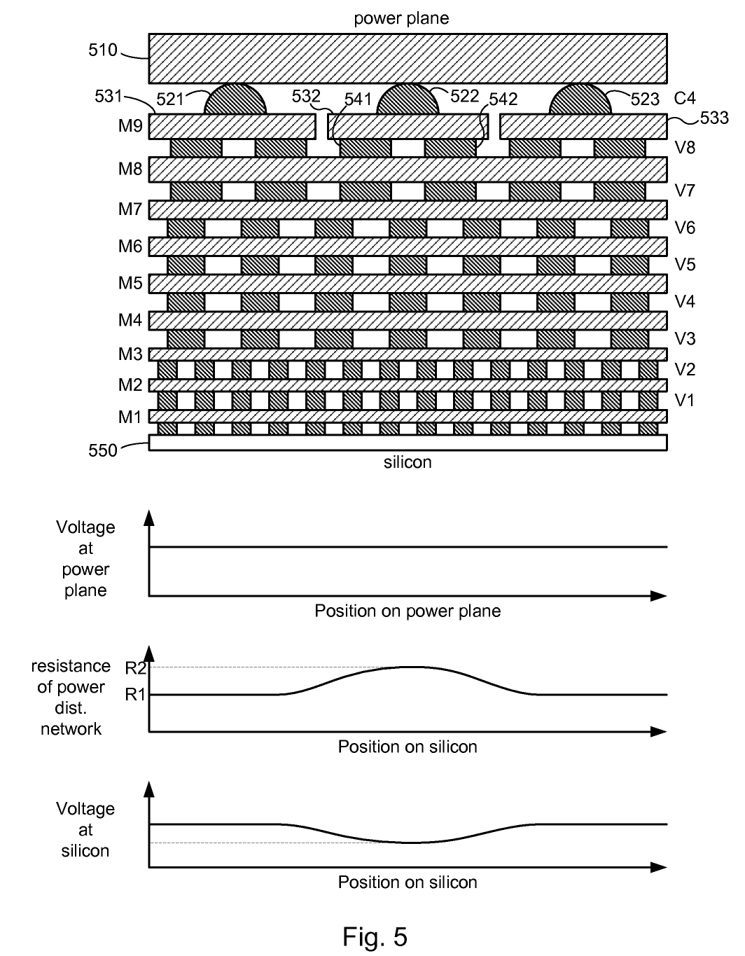

Referring to FIG. 5, a diagram illustrating the effect of locally varying component resistances is shown. At the top of this figure, a side view of the power distribution network is shown. This diagram is similar to the diagram of FIG. 2, except that a power plane 510 is shown connected to C4 contacts 521-523, and the metal traces (531-533) of the top metal layer (M9) are separately depicted. In this example, traces 531-533 (and traces in alternate ones of the metal layers) extend into the page, while the traces of the other metal layers (M8 and the other even-numbered metal layers) extend across the page.

The bottom portion of FIG. 5 includes three graphs. The first is a graph of the voltage at the power plane (510) as a function of position (left to right) on the power plane. The second is a graph of the resistance of the power distribution network as a function of position. This resistance is the overall resistance from the power plane to the corresponding position on the silicon of the integrated circuit. The third graph shows the voltage at the silicon as a function of position.

FIG. 5 assumes that one or more of the components near the center of the power distribution network have higher-than-nominal resistance values. For example, one or more of contact 522, trace 532, or the vias connected to it (e.g., 541, 542) may have resistance values which are substantially higher than nominal. As a result of these higher-than-nominal values, the resistance of the power distribution network (between power plane 510 and silicon 550) will be higher near the above-nominal components, and lower elsewhere. This is illustrated in the resistance graph of FIG. 5. This graph shows that the resistance of the power distribution network is approximately R1 across most of the network, but is higher near the above-nominal components (at the center of the graph.) If a power source is connected to the power plane and a constant voltage is applied across the power distribution network (as shown on the power plane voltage graph,) the voltage that is supplied to the integrated circuit components on the chip will be lower in the region local to the above-nominal components (as shown on the silicon voltage graph at the bottom of FIG. 5.) The dip in voltage results from the higher resistance of the power distribution network in the region of the above-nominal components (as shown in the resistance graph of FIG. 5.)

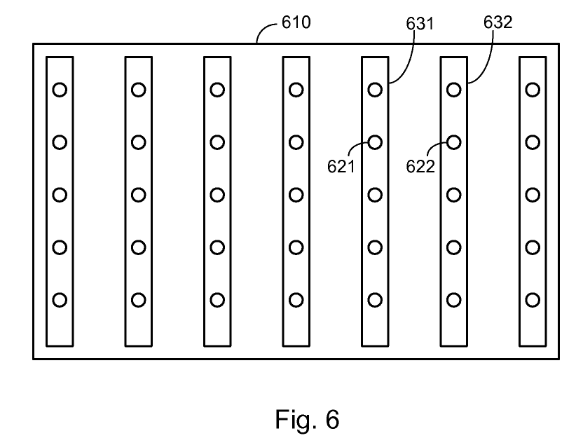

Referring to FIG. 6, a diagram illustrating the configuration of the traces in the top metal layer is shown. FIG. 6 is a top view of a portion of the power distribution network. More specifically, the figure shows power plane 610, elongated traces (e.g., 631, 632) in the top metal layer and contacts (e.g., 621, 622) between the power plane and the traces. Because all of the traces in the top metal layer are oriented in the same direction, the effects of above-nominal resistance values in the contacts and top-metal traces will tend to follow the traces. In other words, the effects will tend to be elongated in the same direction as the traces.

As noted above, if components on the integrated circuit chip are supplied with a voltage that is below a minimum threshold, the components may malfunction. It is therefore necessary to compensate for local voltage drops that may be caused by the power distribution network, as described in connection with FIG. 5. Conventionally, this is accomplished by increasing the voltage applied to the power plane. By increasing the voltage at the power plane, the voltage is at each point on the silicon, including those affected by local increases in the power distribution network resistance, will be increased. By increasing the locally reduced voltages above the minimum threshold voltage, malfunctions will be avoided. The unnecessary increase in the voltages supplied to other areas of the integrated circuit chip, however, will result in wasted power. The present systems and methods enable the compensation of locally reduced voltages, while avoiding voltage increases in areas where they are not required, thereby saving power.

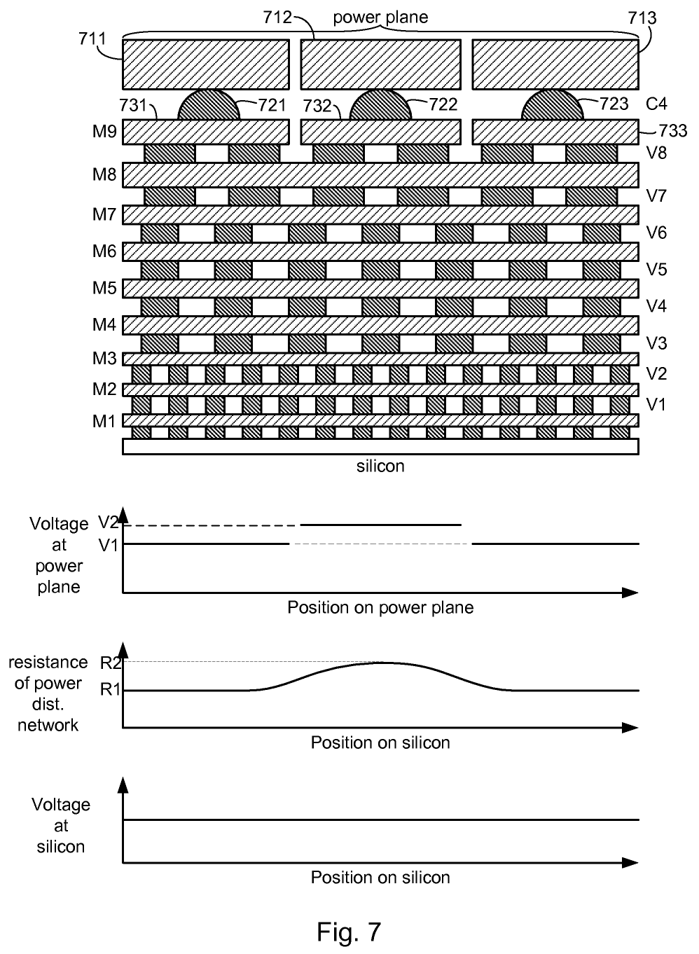

Referring to FIG. 7, a diagram illustrating the use of a divided power plane to achieve localized increases in voltage is shown. FIG. 7 is similar to FIG. 5, showing a side view of a power distribution network, and a set of voltage and resistance curves corresponding to the power distribution network. In FIG. 7, the power plane is divided into several separate pieces (e.g., 711-713.) Each of the pieces of the power plane is connected to a corresponding set of contacts (e.g., 721-723) and traces (e.g., 731-733.) Because the pieces of the power plane are separate, different voltages can be applied to the different pieces.

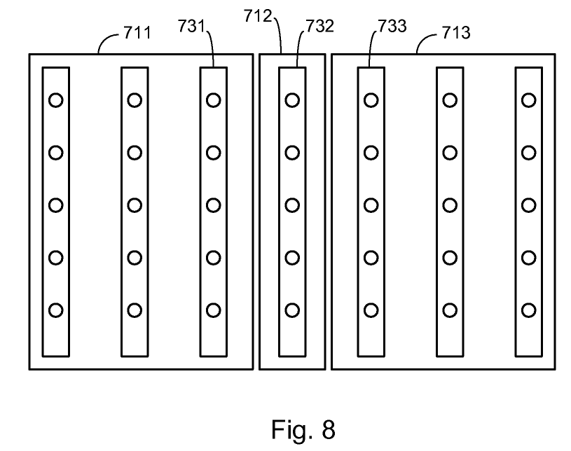

Referring to FIG. 8 a top view of the power distribution network of FIG. 7 is shown. For purposes of clarity, only the power plane, contacts and top-metal traces are depicted. It can be seen in this figure that pieces 711-713 of the power plane are split in the same direction as the traces of the top metal layer. Although the pieces of the power plane may be divided in a different manner, the power plane is split in this direction in this embodiment to allow increased (or decreased) voltages to be applied in the same region as the local effects resulting from above- (or below-) nominal resistance values (which tend, as noted above, to extend in the same direction as the traces.) The traces (e.g., 731-733) are connected to corresponding pieces of the power plane by vias (e.g., 721-723.) In this embodiment, each piece of the power plane may be connected to multiple traces, but each trace is connected to only one of the pieces of the power plane.

Referring again to FIG. 7, the power plane is divided into separate pieces 711-713. “Separate,” as used here, means the pieces of the power plane are not directly connected to each other. The separate pieces of the power plane are not electrically isolated, due to the fact that they are indirectly connected through the power distribution network. Assuming again that one or more of the components in the center of the power distribution network (e.g., contact 722 or trace 732) have resistances that are substantially above their nominal values, the overall resistance of the power distribution network will be locally higher near these components. This is illustrated in the resistance graph (the middle graph at the bottom of FIG. 7.) In order to compensate for this locally increased resistance, a first voltage (V1) is applied to power plane sections 711 and 713, while a second, higher voltage (V2) is applied to power plane section 712. This is illustrated in the power plane voltage graph (the top graph at the bottom of FIG. 7.) Because the higher voltage is applied only to the portion of the power distribution network that exhibits an increased resistance, relative to the remainder of the network, the higher voltage drop across the network is compensated, resulting in a substantially uniform voltage across the entire integrated circuit chip (as shown in the bottom graph of FIG. 7.) It should be noted that the voltage at the silicon is depicted as being constant for purposes of simplicity, and that the term “substantially uniform” is intended to mean that there may still be some variations across the chip.

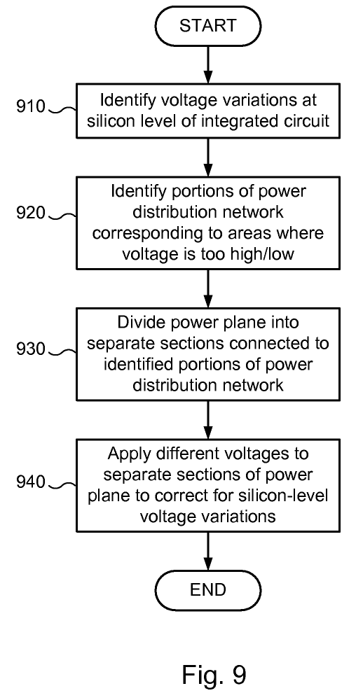

Because the variations in the resistance of the power distribution network, and the corresponding variations in voltage at the silicon of the integrated circuit chip, will generally be different between one device and the next, the power plane cannot be divided in the same manner for each device. It will instead be necessary for each device to determine the corresponding silicon-level voltage variations so that appropriate compensation can be achieved through splitting the power plane and applying different voltages to different sections of the power plane. This process is summarized in the flow diagram of FIG. 9.

Referring to FIG. 9, a flow diagram illustrating a method for correcting silicon-level voltage variations arising from corresponding manufacturing variations is shown. As noted above, the voltage variations at the silicon-level of the integrated circuit are caused by manufacturing variations in the power distribution network. Because these manufacturing variations cannot be predicted, it is first necessary to identify any voltage variations at the interface between the power distribution network and the integrated circuit chip that require correction (910.) These voltages variations may be either greater than an upper threshold above the nominal design voltage, or less than a lower threshold below the nominal design voltage. After it has been determined that there are areas of the integrated circuit chip that have voltages which are too high or too low, corresponding portions of the power distribution network are identified (920.)

As noted above, the component variations that cause the excessive voltage variations on the integrated circuit chip are typically in the top three layers of the power distribution network, so it should be possible to attribute the variations to a particular set of traces in the top metal layer and the corresponding C4 contacts and vias. Once these components have been identified, the power plane can be divided to separate section(s) of the power plane corresponding to the components from other sections (930.) It is contemplated that the power plane will initially be manufactured as a single piece, and that this unitary (one-piece) power plane will be divided (e.g., cut) into separate sections after manufacture of the integrated circuit. After the power plane has been divided into separate sections, two or more different voltages can be applied to the different sections to obtain appropriate voltages at the silicon level of the integrated circuit. In an alternative embodiment, the power plane may initially be tested as a single piece, and this unitary (one-piece) power plane may be replaced by another plane with separate sections after the test. After the unitary power plane is replaced by the multiple-section power plane, two or more different voltages can be applied to the different sections to obtain appropriate voltages at the silicon level of the integrated circuit.

It should be noted that the voltage variations at the silicon level of the integrated circuit chip can be measured, and areas of excessive voltage variations can be determined in various ways. These details are beyond the scope of the present disclosure. Similarly, various techniques can be used to divide that power plane into separate sections, but the details of these techniques will not be set forth here because they are beyond the scope of this disclosure.

It should be noted that alternative embodiments of the invention may include many variations of the features disclosed above. For example, while the disclosure focuses on an exemplary embodiment in which the power plane is split along the direction of the top-level metal traces, alternative embodiments may split the power plane into sections which do not follow the direction or shape of the metal traces. Similarly, while the exemplary embodiment described above corrected for increased resistance in portions of the power distribution network, alternative embodiments may correct for areas of decreased resistance, or areas of both increased and decreased resistance. Still further, alternative embodiments may apply more than two different voltages to the power plane to correct for voltage variations at the seller can level of the integrated circuit. Still other variations will be apparent to those of skill in yard of the invention upon reading the present disclosure.

The benefits and advantages which may be provided by the present invention have been described above with regard to specific embodiments. These benefits and advantages, and any elements or limitations that may cause them to occur or to become more pronounced are not to be construed as critical, required, or essential features of any or all of the claims. As used herein, the terms “comprises,” “comprising,” or any other variations thereof, are intended to be interpreted as non-exclusively including the elements or limitations which follow those terms. Accordingly, a system, method, or other embodiment that comprises a set of elements is not limited to only those elements, and may include other elements not expressly listed or inherent to the claimed embodiment.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein and recited within the following claims.

What is claimed is:

1. A system comprising:
an integrated circuit chip;
a power distribution network coupled to the integrated circuit chip;
a power plane coupled to the power distribution network, wherein the power plane is divided into two or more separate sections and wherein each section is separately connected to the power distribution network; and
one or more power sources coupled to the sections of the power plane and configured to supply a first voltage to a first one of the sections and a second voltage, different from the first voltage, to a second one of the sections, wherein the first and second voltages are selected to produce a substantially uniform voltage across the integrated circuit chip.

2. The system of claim 1, wherein the power distribution network comprises multiple layers of metal traces and multiple layers of vias, wherein the layers of metal traces are alternated with the layers of vias, wherein the power distribution network further comprises a layer of contacts which connect an uppermost one of the metal layers to the power plane.

3. The system of claim 2, wherein the power plane is split in same direction as the uppermost metal layer so that each trace in a top metal layer is connected by contacts to no more than one of the sections of the power plane.

4. The system of claim 1, wherein a first resistance between a first one of the power plane sections and the integrated circuit chip is higher than a second resistance between a second one of the power plane sections and the integrated circuit chip.

5. The system of claim 4, wherein a power source is configured to supply a first voltage to the first one of the sections and a second voltage to the second one of the sections, wherein the first voltage is higher than the second voltage.

6. The system of claim 5, wherein the first voltage is substantially equal to a nominal design voltage at the integrated circuit chip divided by the first resistance, and the second voltage is substantially equal to the nominal design voltage divided by the second resistance.

7. A method comprising:
providing an integrated circuit having a semiconductor chip, a power distribution network connected to the chip, and a power plane connected to the power distribution network, wherein the power plane is divided into two or more separate power plane sections;
applying a first voltage to a first one of the power plane sections; and
applying a second voltage which is different from the first voltage to a second one of the power plane sections;
wherein the first and second voltages are selected to produce a substantially uniform voltage across the integrated circuit chip.

8. The method of claim 7, further comprising identifying a portion of the power distribution network associated with voltages at the semiconductor chip which are less than a threshold value, wherein dividing the power plane into two or more separate sections comprises separating a first section which is connected to the identified portion of the power distribution network from one or more additional sections.

9. The method of claim 8, wherein identifying the portion of the power distribution network associated with voltages at the semiconductor chip which are less than the threshold value comprises identifying one or more traces of an uppermost metal layer of the power distribution network which are nearest to an area on the semiconductor chip at which the voltages are less than the threshold value.

10. The method of claim 8, further comprising applying a first voltage to the identified portion of the power distribution network and applying a second voltage which is less than the first voltage to the additional portions of the power distribution network.

11. A method comprising:
providing an integrated circuit having a semiconductor chip, a power distribution network connected to the chip, and a unitary power plane connected to the power distribution network; and
dividing the power plane into two or more separate sections.

12. The method of claim 11, wherein dividing the power plane into two or more separate sections comprises cutting the power plane in a direction parallel to traces in an uppermost metal layer of the power distribution network.

13. The method of claim 12, further comprising identifying a portion of the power distribution network associated with voltages at the semiconductor chip which are less than a threshold value, wherein dividing the power plane into two or more separate sections comprises separating a first section which is connected to the identified portion of the power distribution network from one or more additional sections.

14. The method of claim 13, wherein identifying the portion of the power distribution network associated with voltages at the semiconductor chip which are less than the threshold value comprises identifying one or more traces of an uppermost metal layer of the power distribution network which are nearest to an area on the semiconductor chip at which the voltages are less than the threshold value.

15. The method of claim 13, further comprising applying a first voltage to the identified portion of the power distribution network and applying a second voltage which is less than the first voltage to the additional portions of the power distribution network.

16. The method of claim 15, further comprising selecting the first and second voltages to produce a substantially uniform voltage across the chip.

17. The method of claim 11, further comprising applying a first voltage to a first one of the power plane sections and applying a second voltage which is different from the first voltage to a second one of the power plane sections.

18. The method of claim 17, further comprising selecting the first and second voltages to produce a substantially uniform voltage across the chip.
